(19) United States
(12) Patent Application Publication
(10) Pub. No.: US 2015/0118770 A1
(43) Pub. Date: Apr. 30, 2015

(54) WAFER-LEVEL PACKAGES HAVING VOIDS FOR OPTO-ELECTRONIC DEVICES

(71) Applicant: Avago Technologies General IP (Singapore) Pte. Ltd., Singapore (SG)

(72) Inventors: Detlef Krabe, Munich (DE); Martin Weigert, Etterzhausen (DE)

(73) Assignee: Avago Technologies General IP (Singapore) Pte. Ltd., Singapore (SG)

(21) Appl. No.: 14/064,406

(22) Filed: Oct. 28, 2013

(51) Int. Cl. H01L 31/18; H01L 31/12; H01L 21/56

(52) U.S. Cl. CPC H01L 31/1876; H01L 21/56; H01L 31/125
USPC 438/25

(57) ABSTRACT

A semiconductor device package is formed by mounting a semiconductor die on an adhesive tape substrate, mounting a sacrificial structure on the adhesive tape substrate, applying molding material on the adhesive tape substrate to embed the die and at least a portion of the at least one sacrificial structure; removing the adhesive tape substrate to define a package assembly, forming a redistribution layer on a surface of the package assembly, and removing sacrificial material to form a void in the molding material having a shape corresponding to a shape of the sacrificial material that was removed.

### BACKGROUND

Embedded Wafer Level Packaging (eWLP) is a semiconductor device packaging technology in which a multiplicity of device packages in which semiconductor dies or chips have been embedded are co-formed with one another as part of a single “wafer” of moldable material and then transformed into individual packages by dicing or singulating the wafer. The process of forming eWLP packages commonly begins with mounting a multiplicity of semiconductor dies or other elements on an adhesive tape base. A robotic pick-and-place machine is commonly employed in the mounting step. Next, a compression molding process is performed to embed or pot the dies or other elements within the molding compound. In compression molding, a layer of molding compound, such as a liquid polymer, is applied to a carrier in which the dies and adhesive tape are retained. Then, the liquid molding compound is distributed over the dies and other elements by compression. The molding compound is then cured to harden it. The resulting assembly is analogous to a wafer of the type traditionally employed in semiconductor fabrication in that the assembly is singulated in a later step of the process. For this reason, such an eWLP assembly is sometimes referred to as a wafer. The molding compound surface is ground down until the assembly has a target thickness, and the tape is removed. Next, a metal layer is applied to one or both surfaces of the assembly by, for example, metal sputtering or electro-plating. Each metal layer is then photolithographically patterned to form a redistribution layer (RDL) that defines electrical signal paths. In some types of eWLP processes, arrays of solder balls are formed on an RDL. The assembly is then diced into individual eWLP packages, each containing one or more semiconductor chips or other elements.

Opto-electronic devices or modules having eWLP packages are known. Opto-electronic modules, such as optical transmitter and receiver modules, are used in optical communication systems. In an optical communication system, an optical transmitter can convert electrical signals that are modulated with information into optical signals for transmission via an optical fiber. An opto-electronic light, source such as a laser, performs the electrical-to-optical signal conversion in an optical transmitter. An optical receiver can receive the optical signals via the optical fiber and recover the information by demodulating the optical signals. An opto-electronic light detector, such as a photodiode, performs the optical-to-electrical signal conversion in an optical receiver. In addition to light sources and light detectors, opto-electronic modules commonly include lenses, reflectors and other optical elements, mechanical structures for retaining such elements, and optical and electrical interconnections. The manner in which such elements are formed within the module affects manufacturing economy. It would be desirable to provide economical methods for forming opto-electronic modules or packages.

### SUMMARY

Embodiments of the present invention relate to a method for forming a semiconductor device package, comprising: mounting at least one semiconductor die on an adhesive tape substrate; mounting at least one sacrificial structure made of a sacrificial material on the adhesive tape substrate; applying molding material on the adhesive tape substrate to embed at least a portion of the at least one semiconductor die and at least a portion of the at least one sacrificial structure; removing the adhesive tape substrate to define a package assembly having at least a portion of the at least one semiconductor die and at least a portion of the at least one sacrificial structure on a first surface of the package assembly; forming at least one metal redistribution layer having a plurality of conductive circuit paths on the first surface of the package assembly, at least a portion of the conductive circuit paths in electrical contact with one or more signal pads of the semiconductor die; and removing at least a portion of the sacrificial material embedded in the molding material to form at least one void in the molding material having a shape corresponding to a shape of the portion of the sacrificial material embedded in the molding material.

Other systems, methods, features, and advantages will be or become apparent to one with skill in the art upon examination of the following figures and detailed description. It is intended that all such additional systems, methods, features, and advantages be included within this description, be within the scope of the specification, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention.

FIG. 1 is a flow diagram illustrating a method for making semiconductor device packages in accordance with exemplary embodiments of the invention.

FIG. 2A is a generalized cross-sectional view illustrating a first portion of an exemplary method for making a semiconductor device package in accordance with a first exemplary embodiment of the invention.

FIG. 2B is a generalized cross-sectional view illustrating a second portion of an exemplary method for making a semiconductor device package in accordance with a first exemplary embodiment of the invention.

FIG. 2C is a generalized cross-sectional view illustrating a third portion of an exemplary method for making a semiconductor device package in accordance with a first exemplary embodiment of the invention.

FIG. 2D is a generalized cross-sectional view illustrating a fourth portion of an exemplary method for making a semiconductor device package in accordance with a first exemplary embodiment of the invention.

FIG. 3A is a generalized cross-sectional view illustrating a first portion of an exemplary method for making a semiconductor device package in accordance with a second exemplary embodiment of the invention.

FIG. 3B is a generalized cross-sectional view illustrating a second portion of an exemplary method for making a semiconductor device package in accordance with the second exemplary embodiment of the invention.

FIG. 3C is a generalized cross-sectional view illustrating a third portion of an exemplary method for making a semiconductor device package in accordance with the second exemplary embodiment of the invention.

FIG. 3D is a generalized cross-sectional view illustrating a fourth portion of an exemplary method for making a semiconductor device package in accordance with the second exemplary embodiment of the invention.

FIG. 4A is a generalized cross-sectional view illustrating a first portion of an exemplary method for making a semiconductor device package in accordance with a third exemplary embodiment of the invention.

FIG. 4B is a generalized cross-sectional view illustrating a second portion of an exemplary method for making a semiconductor device package in accordance with the third exemplary embodiment of the invention.

FIG. 4C is a generalized cross-sectional view illustrating a third portion of an exemplary method for making a semiconductor device package in accordance with the third exemplary embodiment of the invention.

FIG. 4D is a generalized cross-sectional view illustrating a fourth portion of an exemplary method for making a semiconductor device package in accordance with the third exemplary embodiment of the invention.

FIG. 5 is similar to FIG. 4D, showing an alternative configuration.

FIG. 6 is similar to FIG. 5, showing another alternative configuration.

FIG. 7 is a generalized cross-sectional view illustrating a portion of an exemplary method for making a semiconductor device package in accordance with a fourth exemplary embodiment of the invention.

FIG. 8 is a generalized cross-sectional view illustrating a portion of an exemplary method for making a semiconductor device package in accordance with a fifth exemplary embodiment of the invention.

FIG. 9A is a generalized cross-sectional view illustrating a first portion of an exemplary method for making a semiconductor device package in accordance with a sixth exemplary embodiment of the invention.

FIG. 9B is a generalized cross-sectional view illustrating a second portion of an exemplary method for making a semiconductor device package in accordance with the sixth exemplary embodiment of the invention.

FIG. 10A is a generalized cross-sectional view illustrating a first portion of an exemplary method for making a semiconductor device package in accordance with a seventh exemplary embodiment of the invention.

FIG. 10B is a generalized cross-sectional view illustrating a second portion of an exemplary method for making a semiconductor device package in accordance with the seventh exemplary embodiment of the invention.

FIG. 11A is a generalized cross-sectional view illustrating a first portion of an exemplary method for making a semiconductor device package in accordance with an eighth exemplary embodiment of the invention.

FIG. 11B is a generalized cross-sectional view illustrating a second portion of an exemplary method for making a semiconductor device package in accordance with the eighth exemplary embodiment of the invention.

FIG. 12 is a generalized cross-sectional view illustrating a portion of an exemplary method for making a semiconductor device package in accordance with a ninth exemplary embodiment of the invention.

FIG. 13 is a generalized cross-sectional view illustrating a portion of an exemplary method for making a semiconductor device package in accordance with a tenth exemplary embodiment of the invention.

FIG. 14 is a generalized cross-sectional view illustrating a portion of an exemplary method for making a semiconductor device package in accordance with an eleventh exemplary embodiment of the invention.

FIG. 15 is a generalized cross-sectional view illustrating a portion of an exemplary method for making a semiconductor device package in accordance with a twelfth exemplary embodiment of the invention.

FIG. 16A is a generalized cross-sectional view illustrating a first portion of an exemplary method for making a semiconductor device package in accordance with a thirteenth exemplary embodiment of the invention.

FIG. 16B is a generalized cross-sectional view illustrating a second portion of an exemplary method for making a semiconductor device package in accordance with the thirteenth exemplary embodiment of the invention.

FIG. 16C is a generalized cross-sectional view illustrating a third portion of an exemplary method for making a semiconductor device package in accordance with the thirteenth exemplary embodiment of the invention.

FIG. 17A is a generalized cross-sectional view illustrating a portion of an exemplary method for making a semiconductor device package in accordance with the fourteenth exemplary embodiment of the invention.

FIG. 17B is a generalized cross-sectional view illustrating the semiconductor device package of FIG. 17A in use.

FIG. 18A is a generalized cross-sectional view illustrating a portion of an exemplary method for making a semiconductor device package in accordance with a fifteenth exemplary embodiment of the invention.

FIG. 18B is a generalized cross-sectional view illustrating the semiconductor device package of FIG. 18A in use.

FIG. 19A is a generalized cross-sectional view illustrating a first portion of an exemplary method for making a semiconductor device package in accordance with a sixteenth exemplary embodiment of the invention.

FIG. 19B is a generalized cross-sectional view illustrating a second portion of an exemplary method for making a semiconductor device package in accordance with the sixteenth exemplary embodiment of the invention.

FIG. 19C is a generalized cross-sectional view illustrating a third portion of an exemplary method for making a semiconductor device package in accordance with the sixteenth exemplary embodiment of the invention.

FIG. 20A is a generalized cross-sectional view illustrating a first portion of an exemplary method for making a semiconductor device package in accordance with a seventeenth exemplary embodiment of the invention.

FIG. 20B is a generalized cross-sectional view illustrating a second portion of an exemplary method for making a semiconductor device package in accordance with the seventeenth exemplary embodiment of the invention.

FIG. 20C is a generalized cross-sectional view illustrating a third portion of an exemplary method for making a semiconductor device package in accordance with the seventeenth exemplary embodiment of the invention.

### DETAILED DESCRIPTION

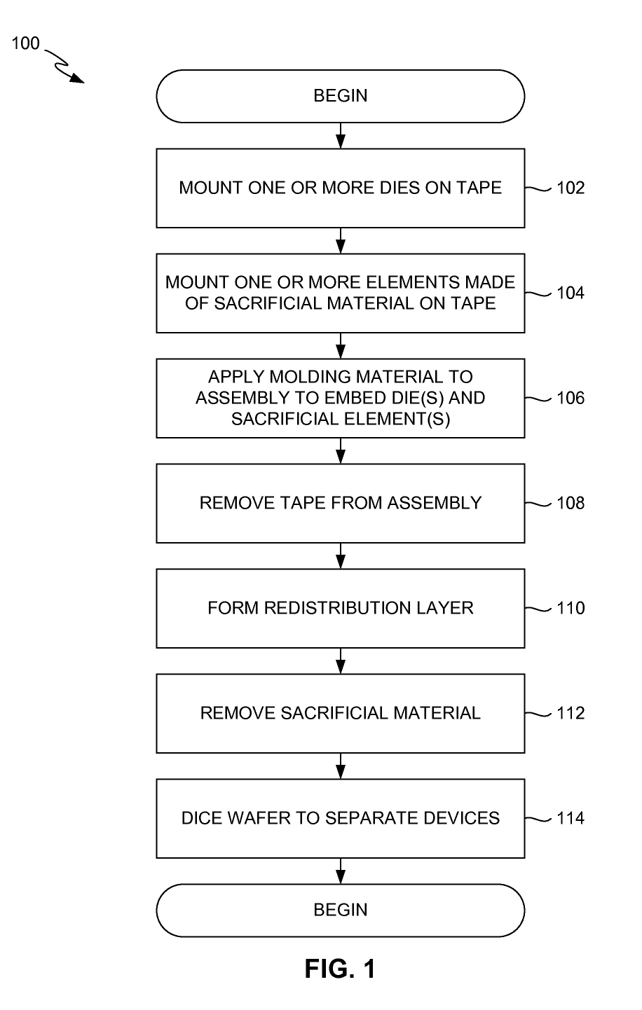

As illustrated in FIG. 1, in embodiments of the invention, a method 100 for making a semiconductor device package begins with mounting one or more semiconductor dies on an adhesive tape substrate, as indicated by block 102. The dies can be mounted in accordance with well-known eWLP principles. For example, a conventional robotic pick-and-place machine (not shown) can be employed to mount the dies. It should be understood that although for purposes of clarity method 100 is described below with respect to a single device package, any number of assemblies (e.g., on the order of tens, hundreds, thousands, etc.) defining such packages can be co-formed as part of the same wafer.

As indicated by block 104, one or more sacrificial structures made of a sacrificial material are also mounted on the adhesive tape substrate. Although for purposes of clarity the exemplary method is described herein with regard to mounting semiconductor dies and sacrificial structures, it should be understood that additional elements similarly can be mounted on the adhesive tape substrate. The sacrificial structures can be mounted in any suitable manner, such as by employing a robotic pick-and-place machine. The sacrificial structures can be made of any suitable material that can be removed by etching, dissolving or thermal decomposition processes, such as processes of the type conventionally used in semiconductor fabrication. Examples of suitable sacrificial materials include metals (e.g., copper), salt parts, polymers (e.g., polycarbonate modifications), and glycol derivatives (e.g., polyethylene carbonate (PEC) and polypropylene carbonate (PPC)).

As indicated by block 106, a molding material is then applied onto the adhesive tape in the form of a layer that covers or embeds at least some portions of the semiconductor dies and sacrificial structures. As well understood in the art, the molding material can comprise, for example, a liquid polymer compound. The molding material is then cured in a conventional manner to harden it. The adhesive tape and the elements mounted on it can be retained in a carrier or mold while the molding material is applied and cured. The mold thus defines the wafer size. The application of molding material as indicated by block 106 can conform to the process commonly known as compression molding. After the molding material has hardened, the surface can be ground down until the assembly has a target thickness.

As indicated by block 108, after the molding material has hardened, the adhesive tape is removed to define a substantially flat package assembly having opposing first and second surfaces. Such a package assembly can be formed contiguously with many other such package assemblies as part of the same wafer. It can be noted that the descriptions herein relating to each package assembly having such a substantially flat shape with opposing first and second surfaces also apply to the wafer as a whole. The descriptions herein thus apply to processes involving any number of (one or more) package assemblies. Note that at least some portions of the semiconductor dies and sacrificial structures are disposed on the first surface of the package assembly as a result of them initially having been mounted on the adhesive tape.

As indicated by block 110, metal redistribution layers (RDLs) are formed on one or both of the first and second surfaces of the package assembly. As well understood in the art, an RDL comprises the circuit traces or conductive circuit paths that define electrical signal interconnections among the semiconductor dies and other circuit elements. Thus, at least some of the conductive circuit paths of the RDL are in contact with one or more signal pads of a semiconductor die. The RDL metal can be applied by, for example, sputtering or electroplating. After the metal is applied, the circuit paths can be formed by photolithographic methods well understood in the art.

As indicated by block 112, at least some of the sacrificial material that is embedded in the molding material is removed by subjecting the package assembly to an etching, dissolving, thermal decomposition, or other suitable process. Suitable processes include, for example, reactive ion etching, aqueous etching, aqueous dissolving, thermal decomposition into volatile products, etc. Removing sacrificial material that has been embedded in the molding material leaves a void in the molding material having a shape corresponding to a shape of the removed volume of sacrificial material.

As indicated by block 114, the wafer is diced or singulated to separate individual package assemblies from each other. Additional conventional steps can be performed before dicing, such as attaching solder bumps or similar electrical interconnections to the wafer.

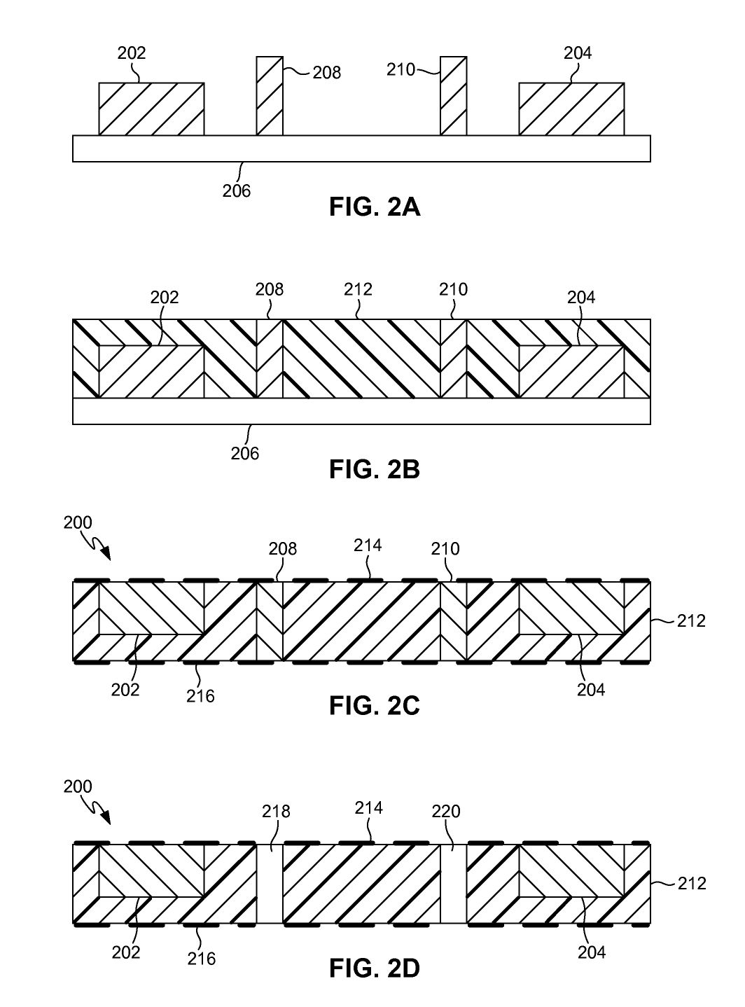

The above-described method 100 can be employed to form various types of packages shown in FIGS. 2-6. As illustrated in FIG. 2A, in a first illustrative or exemplary embodiment, semiconductor dies 202 and 204 are mounted on an adhesive tape substrate 206 in the manner described above with regard to method 100 (FIG. 1). Sacrificial structures 208 and 210, which are made of the above-described sacrificial material, are also mounted on adhesive tape substrate 206 in the manner described above with regard to method 100. In this exemplary embodiment, sacrificial structures 208 and 210 have cylindrical shapes. As illustrated in FIG. 2B, a layer of molding material 212 is then applied onto adhesive tape substrate 206. As described above with regard to method 100, the layer of molding material 212 embeds semiconductor dies 202 and 204, as the thickness of the layer is greater than the height or thickness of semiconductor dies 202 and 204. As the thickness of the layer in the illustrated embodiment is equal to the height or length of sacrificial structures 208 and 210, sacrificial structures 208 and 210 are completely embedded but for their ends that are in contact with adhesive tape substrate 206 and their ends that are exposed and level with the surface of the surrounding molding material. Molding material 212 is then cured to harden it. Although not illustrated, the surface of the hardened molding material 212 can be ground down to provide the layer with a desired thickness. As illustrated in FIG. 2C, adhesive tape substrate 206 is then removed. The resulting package assembly is further processed by forming RDLs 214 and 216 on the first and second surfaces of the package assembly, respectively, as described above with regard to method 100.

The sacrificial material of sacrificial structures 208 and 210 is then removed in the manner described above with regard to method 100 (FIG. 1) to form a semiconductor device package 200. As sacrificial structures 208 and 210 are embedded in molding material 212, removing them leaves voids 218 and 220, respectively, as illustrated in FIG. 2D. Voids 218 and 220 have cylindrical shapes corresponding to the cylindrical shapes of sacrificial structures 208 and 210. Thus, in this embodiment, voids 218 and 220 define apertures that extend completely through the package assembly between the first and second surfaces. That is, each of voids 218 and 220 has openings on (or level with) the first and second surfaces. Although in the illustrated embodiment sacrificial structures 208 and 210 have cylindrical shapes (i.e., circular cross-sectional shapes), in other embodiments similar elongated structures that similarly extend lengthwise completely through the layer of molding material can have other cross-sectional shapes, such as square, hexagonal, etc., or can have various contours or other features. Thus, in other embodiments, apertures having other cross-sectional shapes or features can be formed. It should be noted that a multiplicity of semiconductor device packages 200 can be co-formed on a wafer (not shown), which is then diced in the manner described above with regard to FIG. 1.

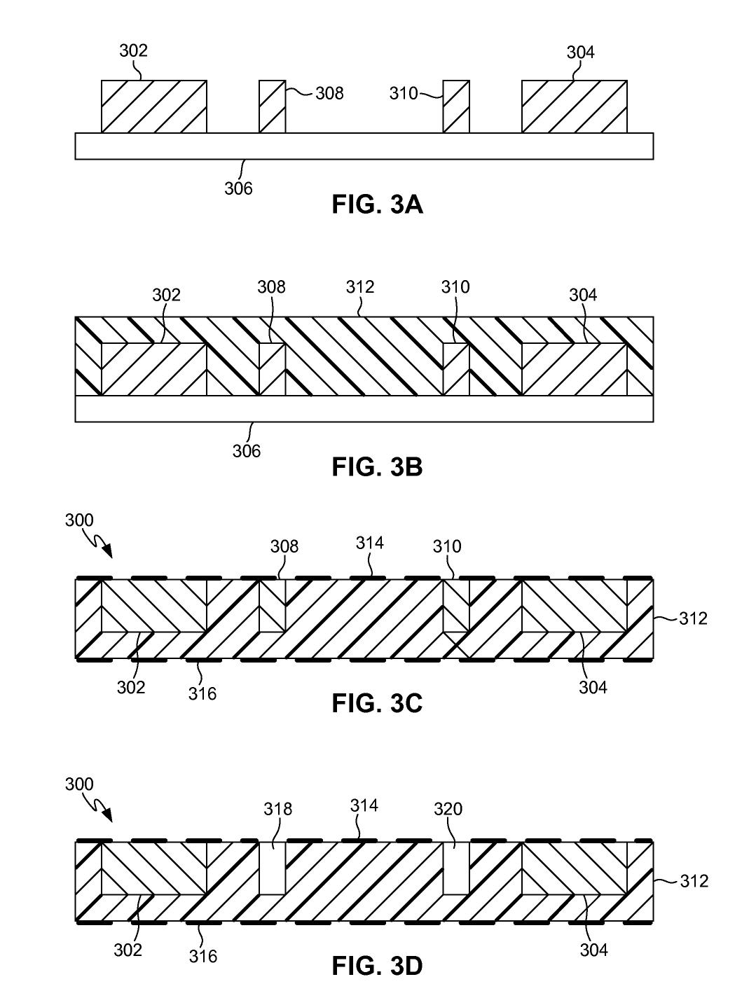

As illustrated in FIG. 3A, in a second illustrative or exemplary embodiment, semiconductor dies 302 and 304 are mounted on an adhesive tape substrate 306 in the manner described above with regard to method 100 (FIG. 1). Sacrificial structures 308 and 310, which are made of the above-described sacrificial material, are also mounted on adhesive tape substrate 306 in the manner described above with regard to method 100. In this embodiment, sacrificial structures 308 and 310 have cylindrical shapes. As illustrated in FIG. 3B, a layer of molding material 312 is then applied onto adhesive tape substrate 306. As described above with regard to method 100, molding material 312 embeds semiconductor dies 302 and 304, as the thickness of the layer is greater than the thickness or height of semiconductor dies 302 and 304. As the thickness of the layer is greater than the height or length of sacrificial structures 308 and 310, sacrificial structures 308 and 310 are completely embedded but for their ends that are in contact with adhesive tape substrate 306. Molding material 312 is then cured to harden it. Although not illustrated, the surface of the hardened molding material 312 can be ground down to provide the layer with a desired thickness. As illustrated in FIG. 3C, adhesive tape substrate 306 is then removed. The resulting package assembly is further processed by forming RDLs 314 and 316 on the first and second surfaces of the package assembly, respectively, as described above with regard to method 100.

The sacrificial material of sacrificial structures 308 and 310 is then removed in the manner described above with regard to method 100 (FIG. 1) to form a semiconductor device package 300. As sacrificial structures 308 and 310 are embedded in molding material 312, removing them leaves voids 318 and 320, respectively, as illustrated in FIG. 3D. Voids 318 and 320 have cylindrical shapes corresponding to the cylindrical shapes of sacrificial structures 208 and 210. Note that while one end of each of voids 318 and 320 is level with the first surface of the package assembly, the other end of each of voids 318 and 320 lies between the first and second surfaces. In other words, in this embodiment, voids 318 and 320 have openings on (or level with) the first surface and bottoms between the first and second surfaces. Although in the illustrated embodiment sacrificial structures 308 and 310 have cylindrical shapes (i.e., circular cross-sectional shapes) in other embodiments similar elongated structures that similarly extend lengthwise only partly through the layer of molding material can have other cross-sectional shapes, such as square, hexagonal, etc., or can have various contours or other features. Thus, in other embodiments, elongated voids (elongated in a direction normal to the first and second surfaces) having other cross-sectional shapes or features can be formed. It should be noted that a multiplicity of semiconductor device packages 300 can be co-formed on a wafer (not shown), which is then diced in the manner described above with regard to FIG. 1.

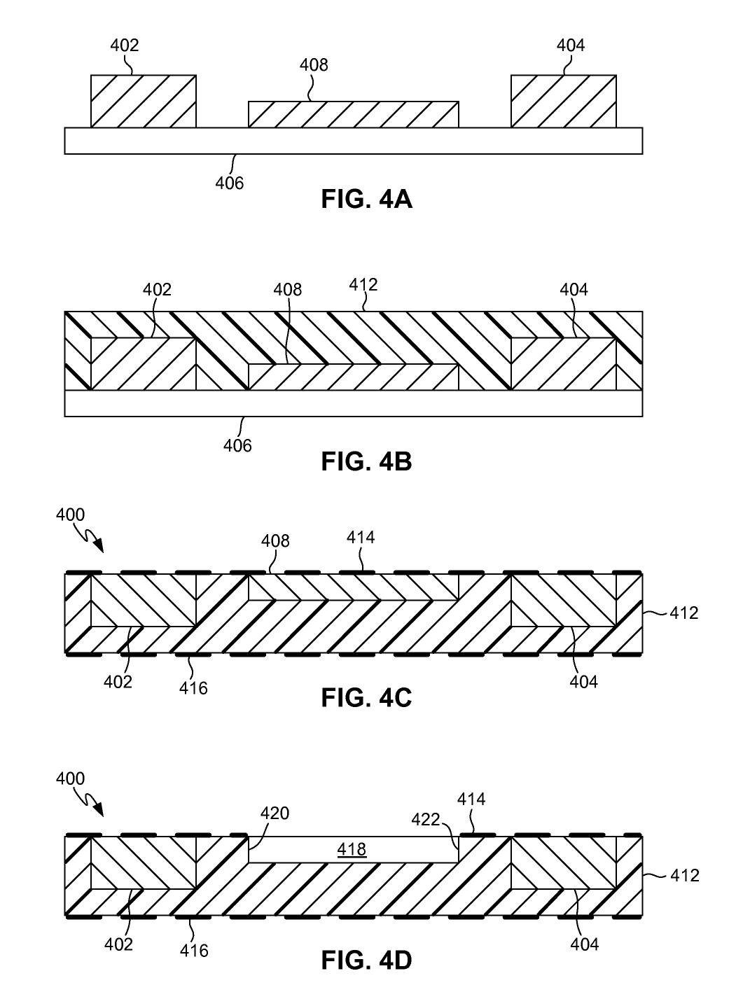

As illustrated in FIG. 4A, in a third illustrative or exemplary embodiment, semiconductor dies 402 and 404 are mounted on an adhesive tape substrate 406 in the manner described above with regard to method 100 (FIG. 1). A sacrificial structure 408, which is made of the above-described sacrificial material, is also mounted on adhesive tape substrate 406 in the manner described above with regard to method 100. In this embodiment, sacrificial structure 408 is bar-shaped. As illustrated in FIG. 4B, a layer of molding material 412 is then applied onto adhesive tape substrate 406. As described above with regard to method 100, molding material 412 embeds semiconductor dies 402 and 404, as the thickness of the layer is greater than the thickness or height of semiconductor dies 402 and 404. As the thickness of the layer is greater than the thickness or height of sacrificial structure 408, sacrificial structure 408 is completely embedded but for the surface or face of sacrificial structure 408 that is in contact with adhesive tape substrate 406. Molding material 412 is then cured to harden it. Although not illustrated, the surface of the hardened molding material 412 can be ground down to provide the layer with a desired thickness. As illustrated in FIG. 4C, adhesive tape substrate 406 is then removed. The resulting package assembly is further processed by forming RDLs 414 and 416 on the first and second surfaces of the package assembly, respectively, as described above with regard to method 100.

The sacrificial material of sacrificial structure 408 is then removed in the manner described above with regard to method 100 (FIG. 1) to form a semiconductor device package 400. As sacrificial structure 408 is embedded in molding material 412, removing it leaves void 418, as illustrated in FIG. 4D. Void 418 has a bar shape (i.e., elongated, with a rectangular cross-section or profile) corresponding to the bar shape of sacrificial structure 408. It can be noted that while one side of void 408 is level with the first surface of the package assembly, the other side of void 408 lies between the first and second surfaces. Thus, in this embodiment, void 418 has a rectangular opening or perimeter on (or level with) the first surface and a bottom between the first and second surfaces. Void 418 also can be characterized as a trough or channel having a depth extending from the first surface to a bottom. Although in the illustrated embodiment sacrificial structure 408 has an elongated rectangular or bar shape, in other embodiments similar elongated bar-shaped structures that similarly extend depth-wise into the layer of molding material can have other cross-sectional shapes, contours or other features. Thus, in other embodiments, elongated voids (elongated in a direction parallel to the first and second surfaces) having other cross-sectional shapes or features can be formed. It should be noted that a multiplicity of semiconductor device packages 400 can be co-formed on a wafer (not shown), which is then diced in the manner described above with regard to FIG. 1.

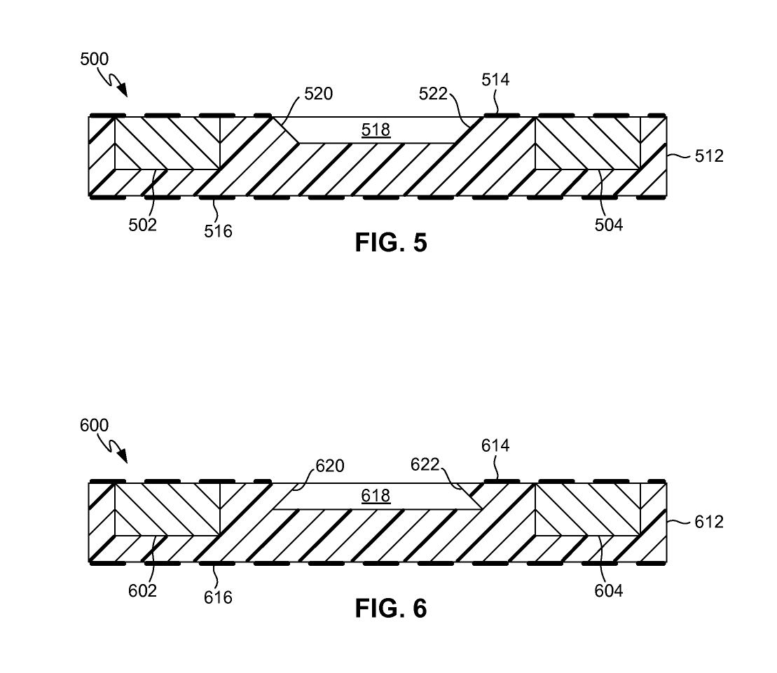

As illustrated in FIG. 5, the method described above with regard to FIGS. 1 and 4A-D can be modified to produce a semiconductor device package 500. Semiconductor device package 500 is similar to above-described semiconductor device package 400 except that semiconductor device package 400 has a bar-shaped void 418 with squared-off ends 420 and 422, whereas semiconductor device package 500 has a bar-shaped void 518 with ends 520 and 522 that slope or angle inwardly from the opening or perimeter of void 518 toward the bottom of void 518. Note that the opening or perimeter of void 518 has a greater area than the bottom of void 518.

The remaining features of semiconductor device package 500 are similar to those of above-described semiconductor device package 400 and are therefore not described in similar detail: semiconductor dies 502 and 504 are similar to semiconductor dies 402 and 404; molding material 512 is similar to molding material 412; and RDLs 514 and 516 are similar to RDLs 414 and 416. The same method described above with regard to FIGS. 1 and 4A-D can be employed to form semiconductor device package 500 except that a sacrificial structure having sloping or angled ends (not shown for purposes of clarity) is employed instead of sacrificial structure 408 with its squared-off ends. In the same manner described above with regard to FIGS. 1 and 4A-D, removing such a sacrificial structure with sloping or angled ends leaves void 518 with correspondingly inwardly sloping or angled ends 520 and 522. It should be noted that a multiplicity of semiconductor device packages 500 can be co-formed on a wafer (not shown), which is then diced in the manner described above with regard to FIG. 1.

As illustrated in FIG. 6, the method described above with regard to FIGS. 1 and 4A-D can be modified to produce a semiconductor device package 600. Semiconductor device package 600 is similar to above-described semiconductor device package 400 except that semiconductor device package 400 has a bar-shaped void 418 with squared-off ends 420 and 422, whereas semiconductor device package 600 has a bar-shaped void 618 with ends 620 and 622 that slope or angle outwardly from the opening or perimeter of void 618 toward the bottom of void 618. Note that the opening or perimeter of void 518 has a smaller area than the bottom of void 618, defining an undercut perimeter.

The remaining features of semiconductor device package 600 are similar to those of above-described semiconductor device package 400 and are therefore not described in similar detail: semiconductor dies 602 and 604; molding material 612; and RDLs 614 and 616. The same method described above with regard to FIGS. 1 and 4A-D can be employed to form semiconductor device package 600 except that a sacrificial structure having sloping or angled ends (not shown for purposes of clarity) is employed instead of sacrificial structure 408 with its squared-off ends. In the same manner described above with regard to FIGS. 1 and 4A-D, removing such a sacrificial structure with sloping or angled ends leaves void 618 with correspondingly outwardly sloping or angled ends 620 and 622. It should be noted that a multiplicity of semiconductor device packages 600 can be co-formed on a wafer (not shown), which is then diced in the manner described above with regard to FIG. 1.

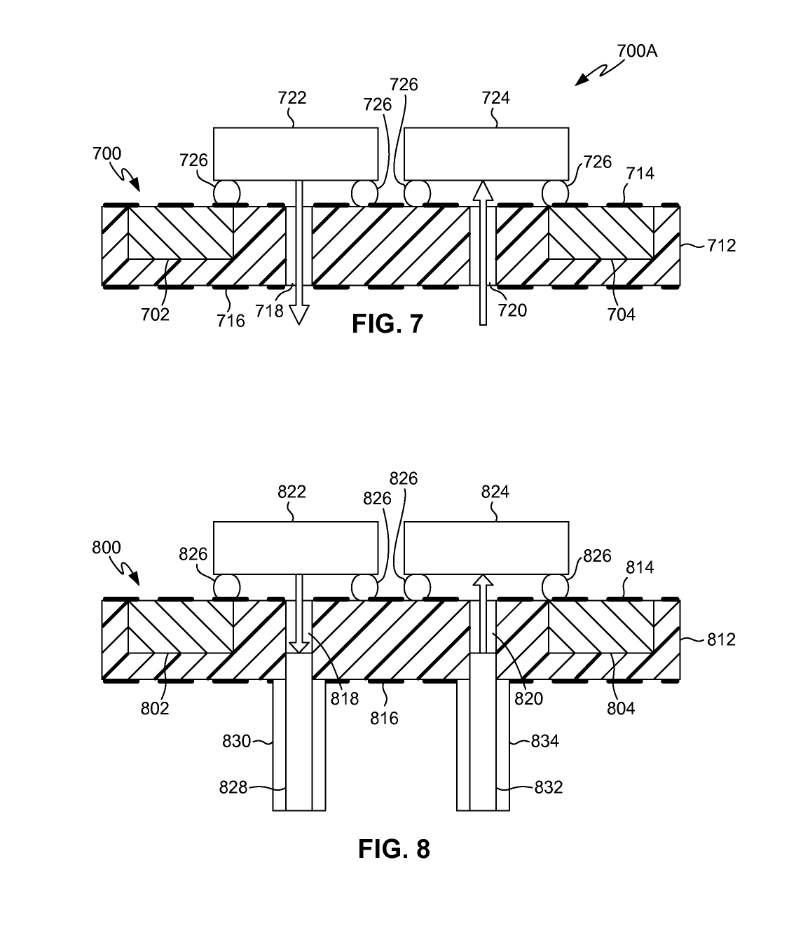

As illustrated in FIG. 7, a semiconductor device package 700 similar to semiconductor device package 200 (FIG. 2D) can be formed in the manner described above with regard to FIGS. 1 and 2A-D. Accordingly, semiconductor dies 702 and 704 are similar to semiconductor dies 202 and 204; molding material 712 is similar to molding material 212; RDLs 714 and 716 are similar to RDLs 214 and 216; and voids 718 and 720 are similar to voids 218 and 220. An opto-electronic transmitter device 722, such as a laser chip, is then mounted on the first surface of semiconductor device package 700, with the optical axis of opto-electronic transmitter device 722 aligned with the longitudinal axis of void 718. An opto-electronic receiver device 724, such as a photodiode chip, is then mounted on the first surface of semiconductor device package 700, with the optical axis of opto-electronic transmitter device 724 aligned with the longitudinal axis of void 720. Solder bumps 726 on opto-electronic transmitter device 722 and opto-electronic receiver device 724 electrically couple these devices to signal paths (not shown) of RDL 714. It should be noted that a multiplicity of the resulting semiconductor transceiver device packages 700A can be co-formed on a wafer (not shown), which is then diced in the manner described above with regard to FIG. 1. In operation, light emitted by opto-electronic transmitter device 722 passes through void 718, as indicated by an arrow in FIG. 7. Similarly, light passing through void 720 impinges on opto-electronic receiver device 724, as indicated by another arrow in FIG. 7.

As illustrated in FIG. 8, a semiconductor device package 800 similar to semiconductor device package 200 (FIG. 2D) can be formed in the manner described above with regard to FIGS. 1 and 2A-D. Accordingly, semiconductor dies 802 and 804 are similar to semiconductor dies 202 and 204; molding material 812 is similar to molding material 212; RDLs 814 and 816 are similar to RDLs 214 and 216; and voids 818 and 820 are similar to voids 218 and 220. An opto-electronic transmitter device 822, such as a laser chip, is then mounted on the first surface of semiconductor device package 800, with the optical axis of opto-electronic transmitter device 822 aligned with the longitudinal axis of void 818. An opto-electronic receiver device 824, such as a photodiode chip, is then mounted on the first surface of semiconductor device package 800, with the optical axis of opto-electronic transmitter device 824 aligned with the longitudinal axis of void 820. Solder bumps 826 on opto-electronic transmitter device 822 and opto-electronic receiver device 824 electrically couple these devices to signal paths (not shown) of RDL 814.

Following dicing, a first optical fiber structure comprising a fiber 828 and outer coating 830 is attached to the second surface of semiconductor device package 800, with the end of fiber 828 retained within void 818. Similarly, a second optical fiber structure comprising a fiber 832 and outer coating 834 is attached to the second surface of semiconductor device package 800, with the end of fiber 832 retained within void 820. In operation, light emitted by opto-electronic transmitter device 822 passes through void 818 and impinges upon the end face of fiber 828, as indicated by an arrow in FIG. 8. Similarly, light emitted from the end face of fiber 832 passes through void 820 and impinges on opto-electronic receiver device 824, as indicated by another arrow in FIG. 8.

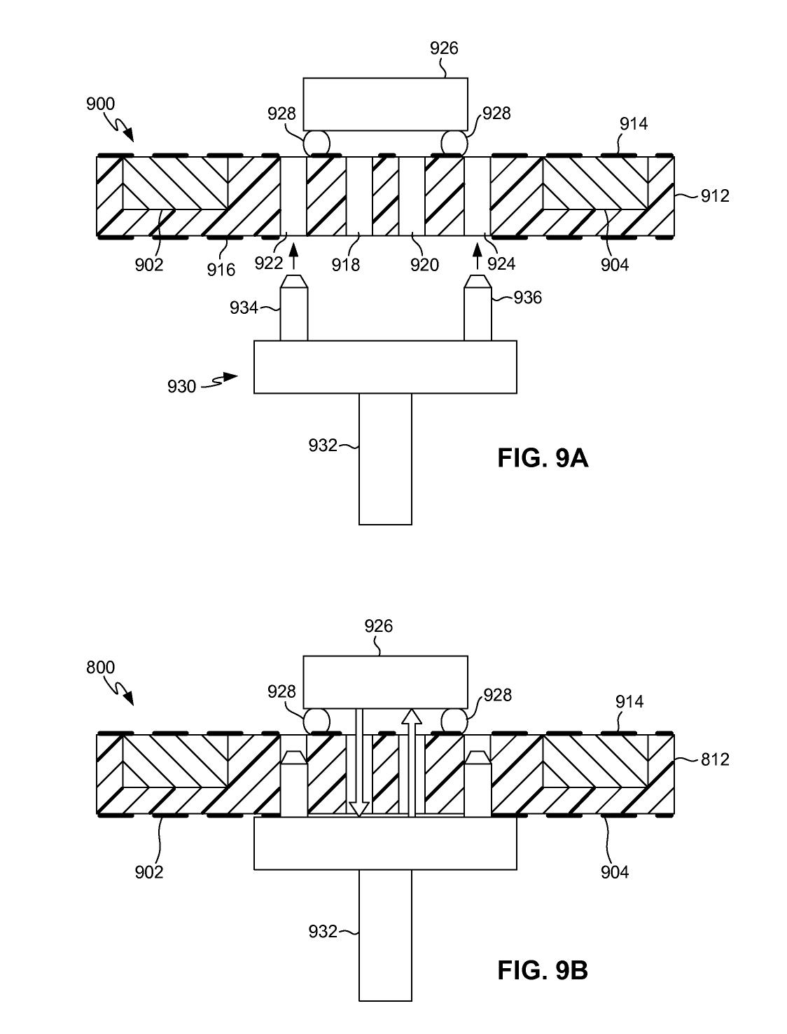

As illustrated in FIG. 9A, a semiconductor device package 900 similar to semiconductor device package 200 (FIG. 2D) can be formed in the manner described above with regard to FIGS. 1 and 2A-D. Accordingly, semiconductor dies 902 and 904 are similar to semiconductor dies 202 and 204; molding material 912 is similar to molding material 212; RDLs 914 and 916 are similar to RDLs 214 and 216; and voids 918, 920, 922 and 924 are similar to voids 218 and 220. An opto-electronic transceiver device 926 having an opto-electronic transmitter and receiver is then mounted on the first surface of semiconductor device package 900, with the transmit and receive optical axes of opto-electronic transceiver device 926 aligned with the longitudinal axes of voids 918 and 920, respectively. Solder bumps 928 on opto-electronic transceiver device 926 electrically couple this device to signal paths (not shown) of RDL 914.

In the embodiment illustrated in FIGS. 9A-B, a connector assembly 930 is then provided. An end of an optical fiber cable 932 is retained in connector assembly 930. Connector assembly 932 has two pins 934 and 936 that are mechanically mateable with voids 922 and 924, respectively. The spacing between pins 934 and 936 corresponds to the spacing between voids 922 and 924. When pins 934 and 936 are mated with voids 922 and 924 in preparation for operation as shown in FIG. 9B, opto-electronic transceiver device 926 is optically aligned with connector assembly 932. In operation, light emitted by opto-electronic transceiver device 926 passes through void 918 and impinges on a light-receiving port (not shown) of connector assembly 930. Similarly, light emitted from a light-emitting port (not shown) of connector assembly 930 passes through void 920 and impinges on opto-electronic transceiver device 926.

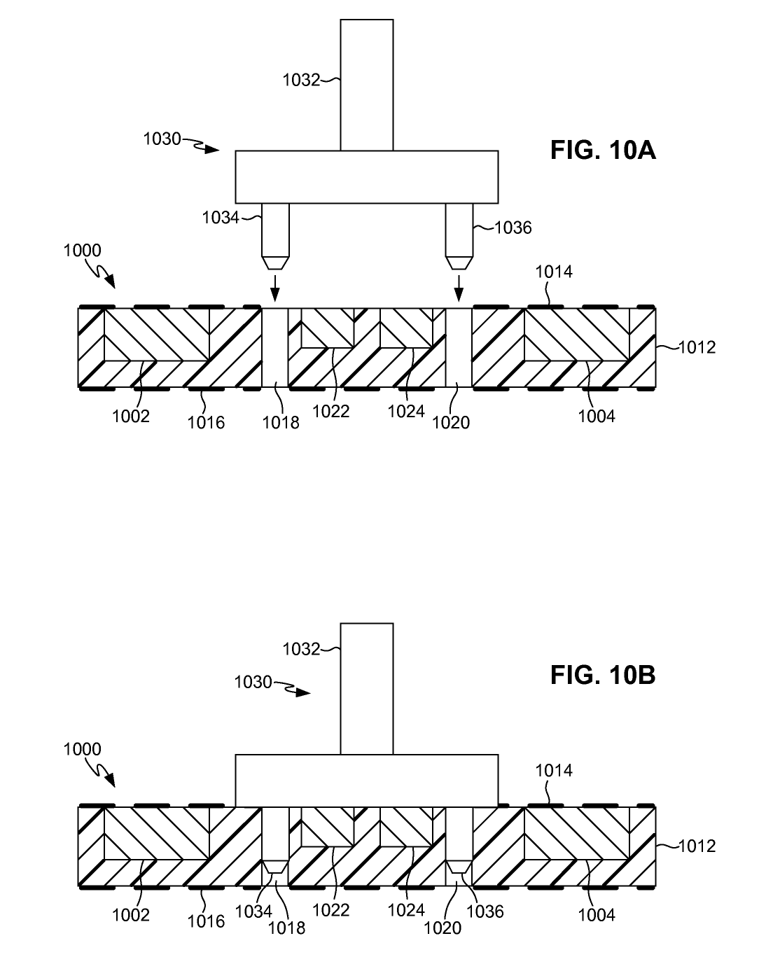

As illustrated in FIG. 10A, a semiconductor device package 1000 is similar to semiconductor device package 200 (FIG. 2D) except that it further includes an opto-electronic transmitter chip (i.e., semiconductor die) 1022 and an opto-electronic receiver chip (i.e., semiconductor die) 1024. Semiconductor device package 1000 thus can be formed in the manner described above with regard to FIGS. 1 and 2A-D, except that the semiconductor chips that are mounted on the adhesive tape (not shown) include not only semiconductor dies 1002 and 1004 but also opto-electronic transmitter chip 1022 and opto-electronic receiver chip 1024. Semiconductor device package 1000 is otherwise similar to above-described semiconductor device package 200: semiconductor dies 1002 and 1004 are similar to semiconductor dies 202 and 204; molding material 1012 is similar to molding material 212; RDLs 1014 and 1016 are similar to RDLs 214 and 216; and voids 1018 and 1020 are similar to voids 218 and 220.

In the embodiment illustrated in FIGS. 10A-B, a connector assembly 1030 is then provided. An end of an optical fiber cable 1032 is retained in connector assembly 1030. Connector assembly 1032 has two pins 1034 and 1036 that are mechanically mateable with voids 1018 and 1020, respectively. The spacing between pins 1034 and 1036 corresponds to the spacing between voids 1018 and 1020. When pins 1034 and 1036 are mated with voids 1018 and 1020 in preparation for operation as shown in FIG. 10B, the optical axis of opto-electronic transmitter chip 1022 is aligned with a light-receiving port (not shown) of connector assembly 1032, and the optical axis of opto-electronic receiver chip 1024 is aligned with a light-emitting port (not shown) of connector assembly 1032. In operation, light emitted by opto-electronic transceiver chip 1022 impinges on the light-receiving port of connector assembly 1030, and light emitted from the light-emitting port of connector assembly 1030 impinges on opto-electronic receiver chip 1024.

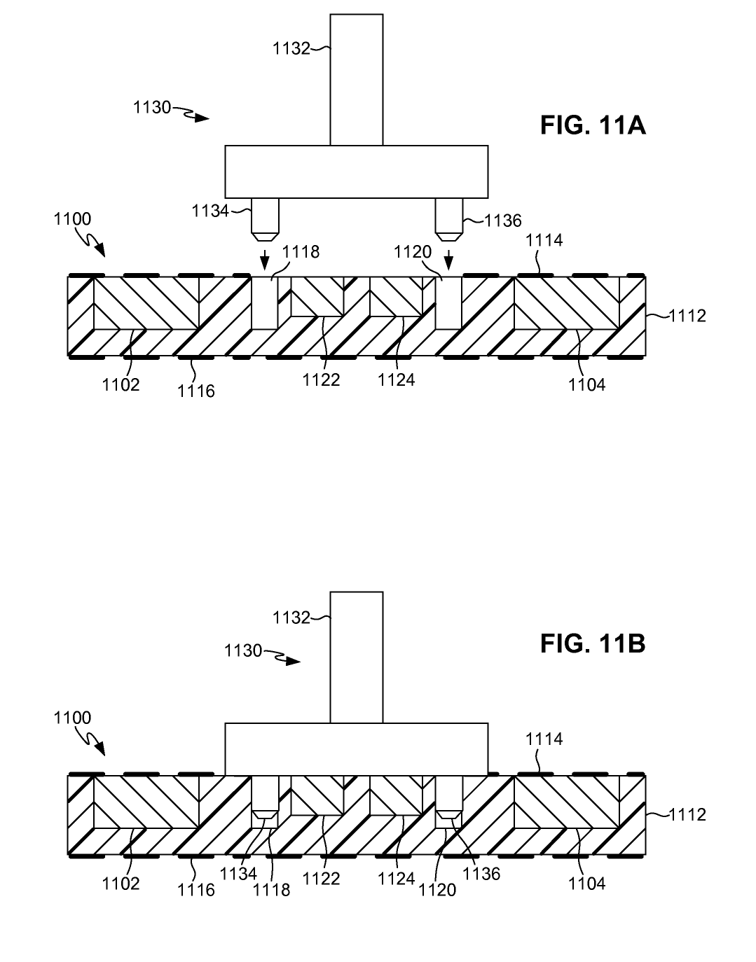

As illustrated in FIG. 11A, a semiconductor device package 1100 is similar to semiconductor device package 300 (FIG. 3D) except that it further includes an opto-electronic transmitter chip (i.e., semiconductor die) 1122 and an opto-electronic receiver chip (i.e., semiconductor die) 1124. Semiconductor device package 1100 thus can be formed in the manner described above with regard to FIGS. 1 and 3A-D, except that the semiconductor chips that are mounted on the adhesive tape (not shown) include not only semiconductor dies 1102 and 1104 but also opto-electronic transmitter chip 1122 and opto-electronic receiver chip 1124. Semiconductor device package 1100 is otherwise similar to above-described semiconductor device package 300: semiconductor dies 1102 and 1104 are similar to semiconductor dies 302 and 304; molding material 1012 is similar to molding material 312; RDLs 1014 and 1016 are similar to RDLs 314 and 316; and voids 1018 and 1020 are similar to voids 318 and 320.

In the embodiment illustrated in FIGS. 11A-B, a connector assembly 1130 is then provided. An end of an optical fiber cable 1132 is retained in connector assembly 1130. Connector assembly 1132 has two pins 1134 and 1136 that are mechanically mateable with voids 1118 and 1120, respectively. The spacing between pins 1134 and 1136 corresponds to the spacing between voids 1118 and 1120. When pins 1134 and 1136 are mated with voids 1118 and 1120 in preparation for operation as shown in FIG. 11B, the optical axis of opto-electronic transmitter chip 1122 is aligned with a light-receiving port (not shown) of connector assembly 1132, and the optical axis of opto-electronic receiver chip 1124 is aligned with a light-emitting port (not shown) of connector assembly 1132. In operation, light emitted by opto-electronic transmitter chip 1122 impinges on the light-receiving port of connector assembly 1130, and light emitted from the light-emitting port of connector assembly 1130 impinges on opto-electronic receiver chip 1124.

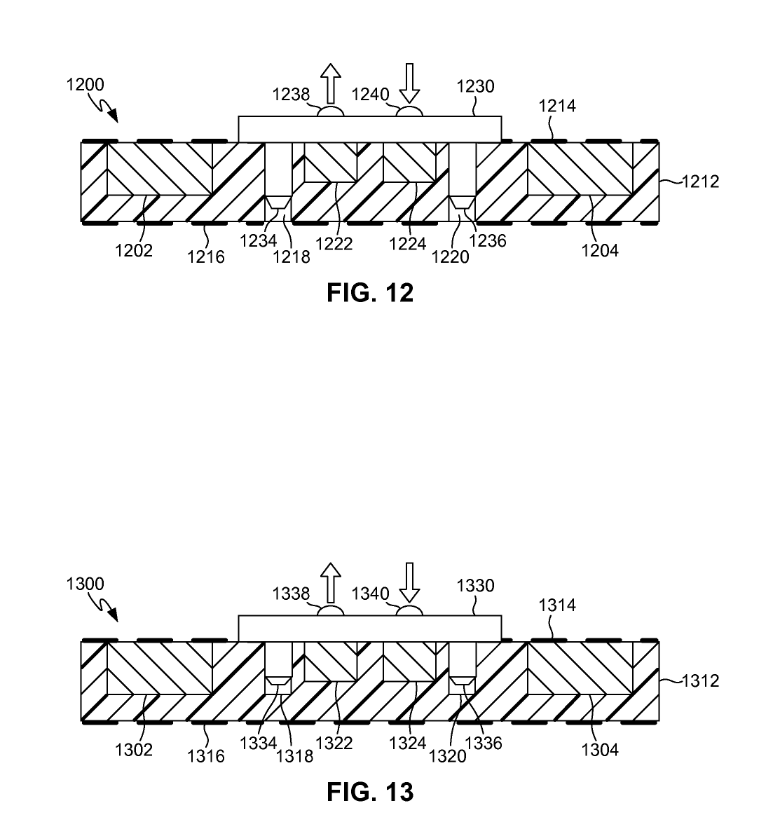

As illustrated in FIG. 12, a semiconductor device package 1200 is similar to semiconductor device package 200 (FIG. 2D) except that it further includes an opto-electronic transmitter chip (i.e., semiconductor die) 1222 and an opto-electronic receiver chip (i.e., semiconductor die) 1224. Semiconductor device package 1200 thus can be formed in the manner described above with regard to FIGS. 1 and 2A-D, except that the semiconductor chips that are mounted on the adhesive tape (not shown) include not only semiconductor dies 1202 and 1204 but also opto-electronic transmitter chip 1222 and opto-electronic receiver chip 1224. Semiconductor device package 1200 is otherwise similar to above-described semiconductor device package 200: semiconductor dies 1202 and 1204 are similar to semiconductor dies 202 and 204; molding material 1212 is similar to molding material 212; RDLs 1214 and 1216 are similar to RDLs 214 and 216; and voids 1218 and 1220 are similar to voids 218 and 220.

In the embodiment illustrated in FIG. 12, a lens device 1230 is further included. Lens device 1230 has two pins 1234 and 1236 that are mechanically mateable with voids 1218 and 1220, respectively. The spacing between pins 1234 and 1236 corresponds to the spacing between voids 1218 and 1220. Lens device 1230 also has two lenses 1238 and 1240. When pins 1234 and 1236 are mated with voids 1218 and 1220, the optical axis of opto-electronic transmitter chip 1222 is aligned with lens 1238, and the optical axis of opto-electronic receiver chip 1224 is aligned with lens 1240. In operation, light emitted by opto-electronic transmitter chip 1222 is transmitted through lens 1238, and light received through lens 1240 impinges on opto-electronic receiver chip 1224.

As illustrated in FIG. 13, a semiconductor device package 1300 is similar to semiconductor device package 300 (FIG. 3D) except that it further includes an opto-electronic transmitter chip (i.e., semiconductor die) 1322 and an opto-electronic receiver chip (i.e., semiconductor die) 1324. Semiconductor device package 1300 thus can be formed in the manner described above with regard to FIGS. 1 and 3A-D, except that the semiconductor chips that are mounted on the adhesive tape (not shown) include not only semiconductor dies 1302 and 1304 but also opto-electronic transmitter chip 1322 and opto-electronic receiver chip 1324. Semiconductor device package 1300 is otherwise similar to above-described semiconductor device package 300: semiconductor dies 1302 and 1304 are similar to semiconductor dies 302 and 304; molding material 1312 is similar to molding material 312; RDLs 1314 and 1316 are similar to RDLs 314 and 316; and voids 1318 and 1320 are similar to voids 318 and 320.

In the embodiment illustrated in FIG. 13, a lens device 1330 is further included. Lens device 1330 has two pins 1334 and 1336 that are mechanically mateable with voids 1318 and 1320, respectively. The spacing between pins 1334 and 1336 corresponds to the spacing between voids 1318 and 1320. Lens device 1330 also has two lenses 1338 and 1340. When pins 1334 and 1336 are mated with voids 1318 and 1320, the optical axis of opto-electronic transmitter chip 1322 is aligned with lens 1338, and the optical axis of opto-electronic receiver chip 1324 is aligned with lens 1340. In operation, light emitted by opto-electronic transmitter chip 1322 is transmitted through lens 1338, and light received through lens 1340 impinges on opto-electronic receiver chip 1324.

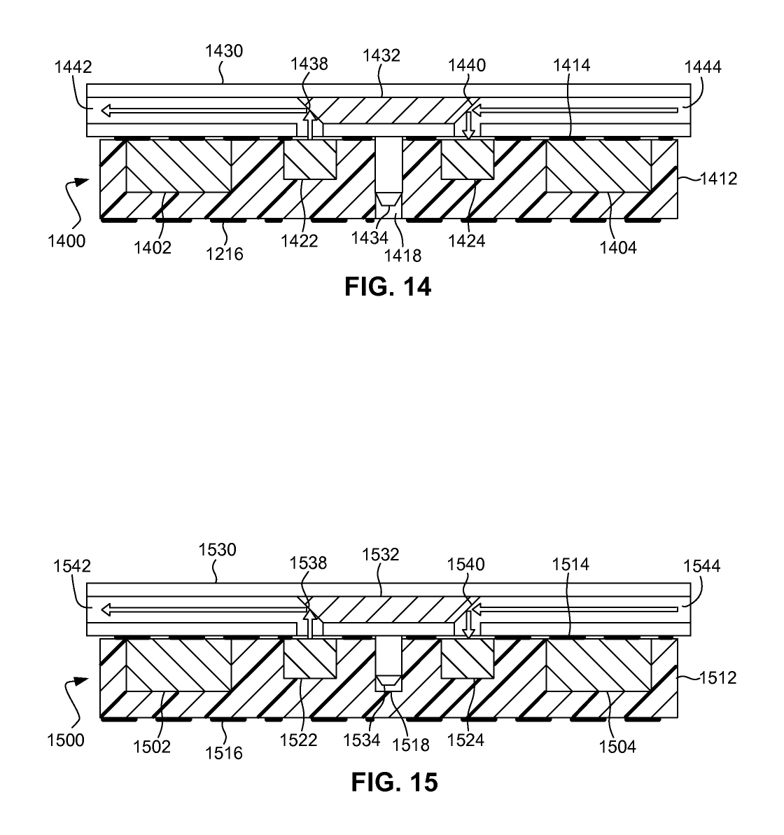

As illustrated in FIG. 14, a semiconductor device package 1400 is similar to semiconductor device package 200 (FIG. 2D) except that there is only a single void 1418 and further includes an opto-electronic transmitter chip (i.e., semiconductor die) 1422 and an opto-electronic receiver chip (i.e., semiconductor die) 1424. Semiconductor device package 1400 thus can be formed in the manner described above with regard to FIGS. 1 and 2A-D, except that the semiconductor chips mounted on the adhesive tape (not shown) include not only semiconductor dies 1402 and 1404 but also opto-electronic transmitter chip 1422 and opto-electronic receiver chip 1424. Semiconductor device package 1400 is otherwise similar to above-described semiconductor device package 200: semiconductor dies 1402 and 1404 are similar to semiconductor dies 202 and 204; molding material 1412 is similar to molding material 212; RDLs 1414 and 1416 are similar to RDLs 214 and 216; and void 1418 is similar to voids 218 and 220.

In the embodiment illustrated in FIG. 14, a reflector device 1430 is further included. Reflector device 1430 has a pin 1434 that is mechanically mateable with void 1418. Reflector device 1430 also has a reflector 1432 with two angled reflective surfaces 1438 and 1440. When pin 1434 is mated with void 1418, the optical axis of opto-electronic transmitter chip 1422 is aligned with reflective surface 1438, and the optical axis of opto-electronic receiver chip 1424 is aligned with reflective surface 1440. Reflective surfaces 1438 and 1440 are oriented at 45-degree angles to these optical axes. In operation, light emitted by opto-electronic transmitter chip 1422 impinges upon reflective surface 1438, which reflects the light 90 degrees through a light-emitting port 1442 of reflector device 1430. Similarly, light entering a light-receiving port 1444 of reflector device 1430 impinges on reflective surface 1440, which reflects the light 90 degrees onto opto-electronic receiver chip 1424.

As illustrated in FIG. 15, a semiconductor device package 1500 is similar to semiconductor device package 300 (FIG. 3D) except that there is only a single void 1518 and further includes an opto-electronic transmitter chip (i.e., semiconductor die) 1522 and an opto-electronic receiver chip (i.e., semiconductor die) 1524. Semiconductor device package 1500 thus can be formed in the manner described above with regard to FIGS. 1 and 3A-D, except that the semiconductor chips mounted on the adhesive tape (not shown) include not only semiconductor dies 1502 and 1504 but also opto-electronic transmitter chip 1522 and opto-electronic receiver chip 1524. Semiconductor device package 1500 is otherwise similar to above-described semiconductor device package 300: semiconductor dies 1502 and 1504 are similar to semiconductor dies 302 and 304; molding material 1512 is similar to molding material 312; RDLs 1514 and 1516 are similar to RDLs 314 and 316; and void 1518 is similar to voids 318 and 320.

In the embodiment illustrated in FIG. 15, a reflector device 1530 is further included. Reflector device 1530 has a pin 1534 that is mechanically mateable with void 1518. Reflector device 1530 also has a reflector 1532 with two angled reflective surfaces 1538 and 1540. When pin 1534 is mated with void 1518, the optical axis of opto-electronic transmitter chip 1522 is aligned with reflective surface 1538, and the optical axis of opto-electronic receiver chip 1524 is aligned with reflective surface 1540. Reflective surfaces 1538 and 1540 are oriented at 45-degree angles to these optical axes. In operation, light emitted by opto-electronic transmitter chip 1522 impinges upon reflective surface 1538, which reflects the light 90 degrees through a light-emitting port 1542 of reflector device 1530. Similarly, light entering a light-receiving port 1544 of reflector device 1530 impinges on reflective surface 1540, which reflects the light 90 degrees onto opto-electronic receiver chip 1524.

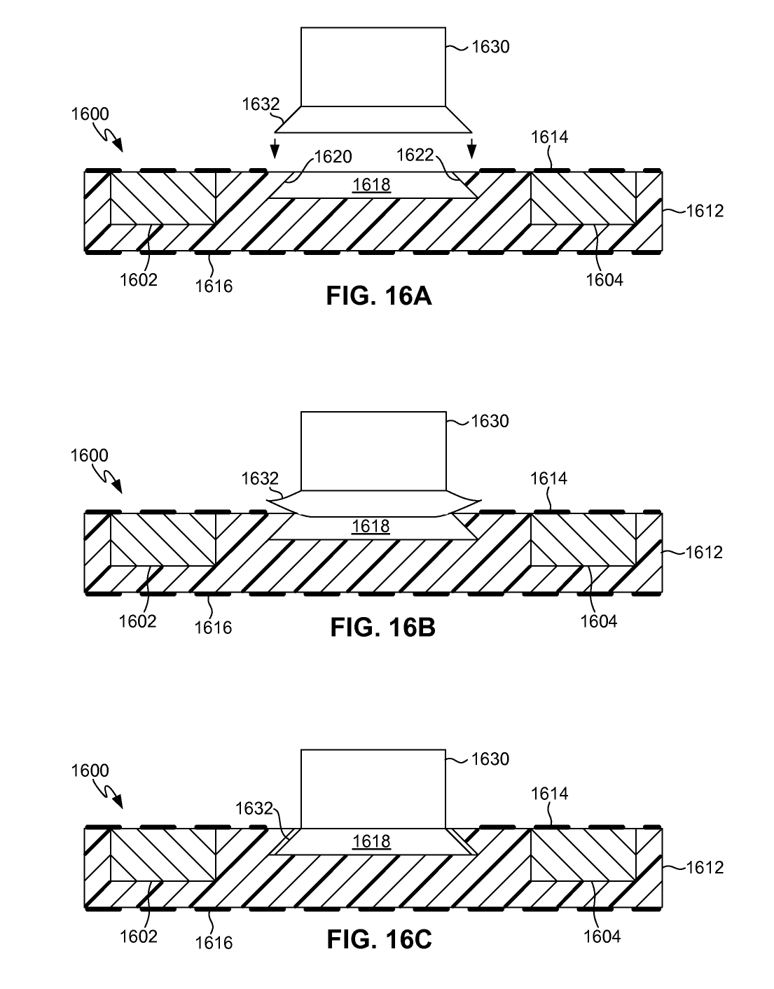

As illustrated in FIG. 16, a semiconductor device package 1600 is similar to semiconductor device package 600 (FIG. 6) and thus can be formed in the manner described above with regard to FIGS. 1 and 6. Accordingly, semiconductor dies 1602 and 1604 are similar to semiconductor dies 602 and 604; molding material 1612 is similar to molding material 612; RDLs 1614 and 1616 are similar to RDLs 614 and 616; and void 1618 is similar to void 618. Void 1618 has two opposing outwardly (and downwardly) sloping ends 1620 and 1622 that are similar to ends 620 and 622, respectively, described above with regard to FIG. 6.

In the embodiment illustrated in FIGS. 16A-C, a fastening member 1630 is further included. Fastening member 1630 can be part of another assembly (not shown) that is to be fastened or attached to semiconductor device package 600 or can be a fastener used for such a purpose. Fastening member 1630 has a base 1632 with a shape substantially complementary to the shape of void 1618. Base 1632 and void 1618 form a snap-fit mechanical engagement. Base 1632 can be made of a resilient plastic material suitable for a snap engagement, as understood by persons skilled in the art. When base 1632 is urged into contact with the portion of semiconductor device package 1600 that defines the perimeter of void 1618, the contact force bends base 1632 in a resilient manner until it enters void 1618, as illustrated in FIG. 16B. Having entered void 1618, base 1632 resiliently relaxes or snaps back to its unflexed shape. As the shapes of base 1632 and void 1618 are complementary, fastening member 1630 remains mechanically engaged with semiconductor device package 1600 until such time as a sufficient force is applied to snap them out of engagement with each another. Note that for purposes of clarity the scale of FIGS. 16A-C is highly exaggerated, and the snap-engagement features are depicted in a generalized manner. Persons skilled in the art are capable of designing suitable snap-fit engagements and similar mechanical engagements in view of the descriptions herein. Also, although in the exemplary embodiment illustrated in FIGS. 16A-C the engagement between fastening member 1630 and void 1618 is a snap-fit engagement, in other embodiments the engagement between such a fastening member and a void having a complementary shape to the fastening member can be of any other suitable type, such as a bayonet engagement in which a fastening member slides into a void having a complementary shape, or a screw-in engagement in which a generally helically shaped fastening member screws into a void having a complementary shape.

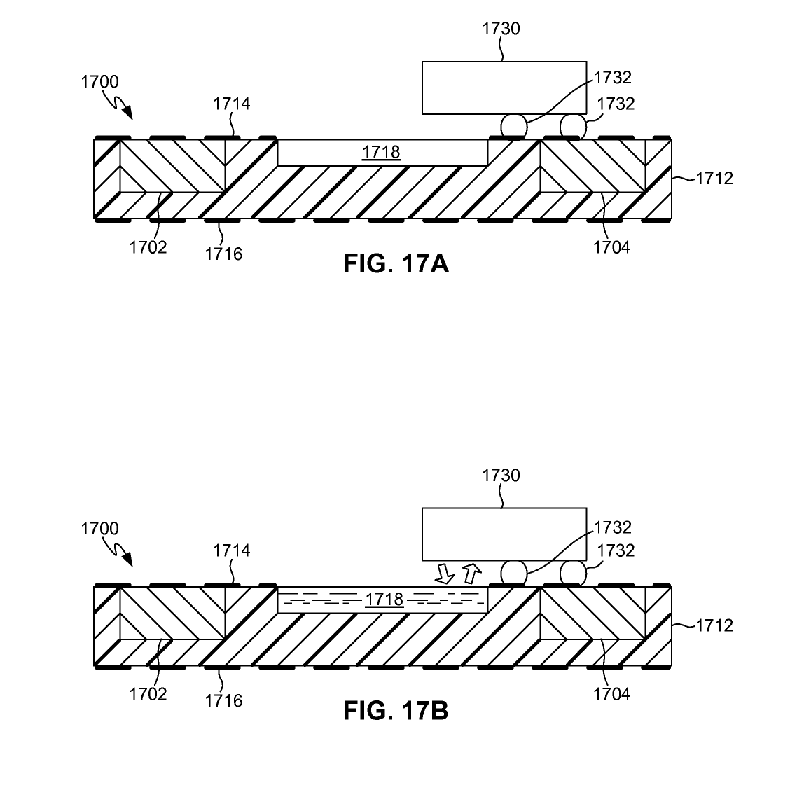

As illustrated in FIG. 17A, a semiconductor device package 1700 is similar to semiconductor device package 400 (FIGS. 4A-D) and thus can be formed in the manner described above with regard to FIGS. 1 and 4A-D. Accordingly, semiconductor dies 1702 and 1704 are similar to semiconductor dies 402 and 404; molding material 1712 is similar to molding material 412; RDLs 1714 and 1716 are similar to RDLs 414 and 416; and void 1718 is similar to void 418.

In the embodiment illustrated in FIGS. 17A-B, a lab-on-a-chip (LOC) transceiver 1730 is further included. As well understood by persons skilled in the art, a lab-on-a-chip (LOC) device implements some of the functionalities of a biological laboratory on a single semiconductor substrate through a network of one or more micro-fluidic channels. Many types of LOC devices are known. Although the various types of LOC devices differ in how they process the measured signals, many such devices share the characteristics of projecting optical signals into a fluid sample and optically detecting changes in the optical signals resulting from their interaction with the fluid sample. Accordingly, an LOC commonly comprises a laser or similar light source and a photodiode or similar light detector, as well as processing circuitry for driving the laser and for analyzing the detected optical signals. Although not separately shown, it should be understood that LOC transceiver 1730 includes an opto-electronic transmitter such as a laser, an opto-electronic receiver such as a photodiode, and processing circuitry. As persons skilled in the art are capable of providing such LOCs and their transceivers, further details of the structure and operation of LOC transceiver 1730 are not described herein. Examples of suitable LOCs include those available from LioniX BV of Enschede, The Netherlands. Solder bumps 1732 on LOC transceiver 1730 electrically couple LOC transceiver 1730 to signal paths (not shown) of RDL 1714.

As illustrated in FIG. 17B, void 1718 serves as a cavity or vessel for containing a fluid sample to be analyzed. Optical transmit and receive axes of LOC transceiver 1730 are aligned with a region of void 1718 in which the fluid is accumulated. LOC transceiver 1730 is mounted on the first surface of semiconductor device package 1700 such that LOC transceiver 1730 straddles the first surface and void 1718. That is, one portion of LOC transceiver device 1730 is mounted on the first surface, while another portion of LOC transceiver overhangs void 1718 in a cantilevered arrangement. After the fluid is introduced into void 1718, LOC transceiver 1730 is activated to cause LOC transceiver 1730 to project light into the fluid in void 1718. At the same time, LOC transceiver 1730 detects the light emitted from (e.g., reflected by) the fluid in void 1718. Processing circuitry (not shown) can analyze differenced between the projected and detected light in a manner well known in the art.

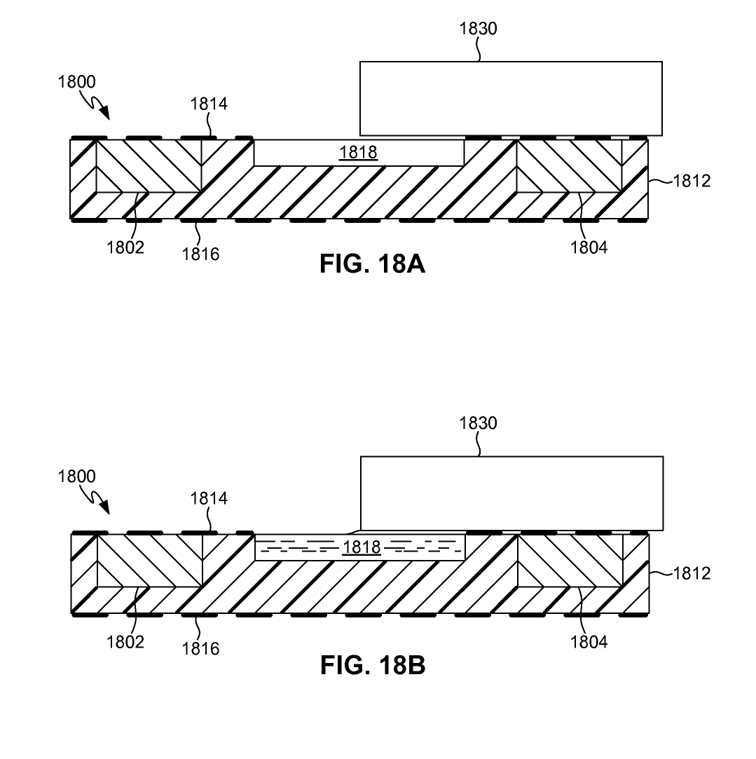

As illustrated in FIG. 18A, a semiconductor device package 1800 is similar to semiconductor device package 400 (FIGS. 4A-D) and thus can be formed in the manner described above with regard to FIGS. 1 and 4A-D. Accordingly, semiconductor dies 1802 and 1804 are similar to semiconductor dies 402 and 404; molding material 1812 is similar to molding material 412; RDLs 1814 and 1816 are similar to RDLs 414 and 416; and void 1818 is similar to void 418.

In the embodiment illustrated in FIGS. 18A-B, a cover 1830 is further included. Cover 1830 is depicted in generalized form in FIGS. 18A-B for illustrative purposes but can have any suitable shape and can serve to cover any portion of semiconductor device package 1800. Cover 1830 is mounted on the first surface of semiconductor device package 1800 such that cover 1830 straddles the first surface and void 1818. That is, one portion of cover 1830 is mounted on the first surface, while another portion of cover 1830 overhangs void 1818 in a cantilevered arrangement. Void 1818 serves as a cavity or channel for introducing a liquid adhesive. As illustrated in FIG. 18B, after void 1818 is filled with a liquid adhesive (up to nearly the level of the first surface), capillary action draws the adhesive into the thin spaces between the first surface and cover 1830 and between the surface of the pool of adhesive and cover 1830.

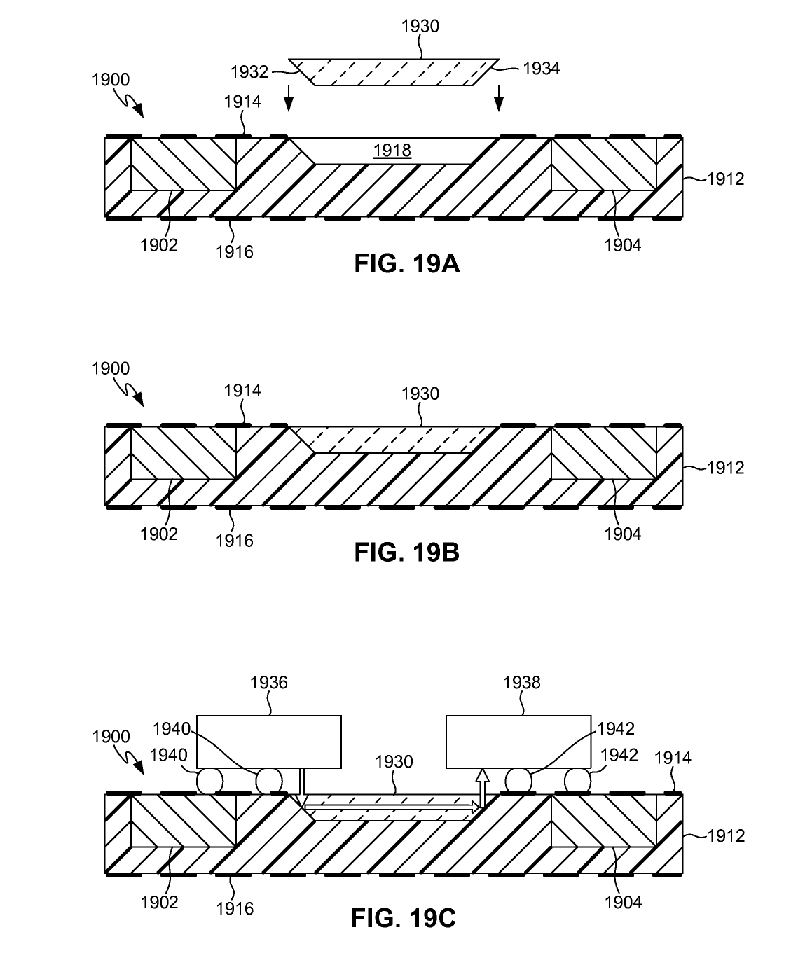

As illustrated in FIG. 19A, a semiconductor device package 1900 is similar to semiconductor device package 500 (FIGS. 5A-D) and thus can be formed in the manner described above with regard to FIGS. 1 and 5A-D. Accordingly, semiconductor dies 1902 and 1904 are similar to semiconductor dies 502 and 504; molding material 1912 is similar to molding material 512; RDLs 1914 and 1916 are similar to RDLs 514 and 516; and void 1918 is similar to void 518.

As illustrated in FIGS. 19A-B, a reflector device 1930 is mounted in void 1918. Reflector device 1930 has a shape that is complementary to the shape of void 1918. Reflector device 1930 may comprise an optically transparent material such as glass or plastic. An optically reflective material, such as a metal coating, is applied to the angled ends 1932 and 1934 of reflector device 1930. Note that ends 1932 and 1934 are oriented at an oblique angle, such as 45 degrees, with respect to the first surface.

As illustrated in FIG. 19C, an opto-electronic transmitter device 1936 and an opto-electronic receiver device 1938 are mounted on the first surface of semiconductor device package 1900 such that each straddles the first surface and void 1918. That is, one portion of opto-electronic transmitter device 1936 is mounted on the first surface, while another portion of opto-electronic transmitter device 1936 overhangs void 1918 in a cantilevered arrangement. Similarly, one portion of opto-electronic receiver device 1938 is mounted on the first surface, while another portion of opto-electronic receiver device 1938 overhangs void 1918 in a cantilevered arrangement. Solder bumps 1940 and 1942 on opto-electronic transmitter device 1936 and opto-electronic receiver device 1938, respectively, electrically couple opto-electronic transmitter device 1936 and opto-electronic receiver device 1938 to signal paths (not shown) of RDL 1914. The optical axes of opto-electronic transmitter device 1936 and an opto-electronic receiver device 1938, respectively, are aligned with the reflective ends 1932 and 1934, respectively, of reflector device 1930.

In operation, opto-electronic transmitter device 1936 emits optical signals, which reflective end 1932 of reflector device 1930 reflects 90 degrees through reflector device 1930 in a direction parallel to the first surface. Void 1918 thus defines a channel through which the optical signals pass. More specifically, the optical signals are transmitted through the transparent material of reflector device 1930. At the other end of the channel defined by void 1918, the other reflective end 1934 of reflector device 1930 reflects the optical signals 90 degrees onto opto-electronic receiver device 1938.

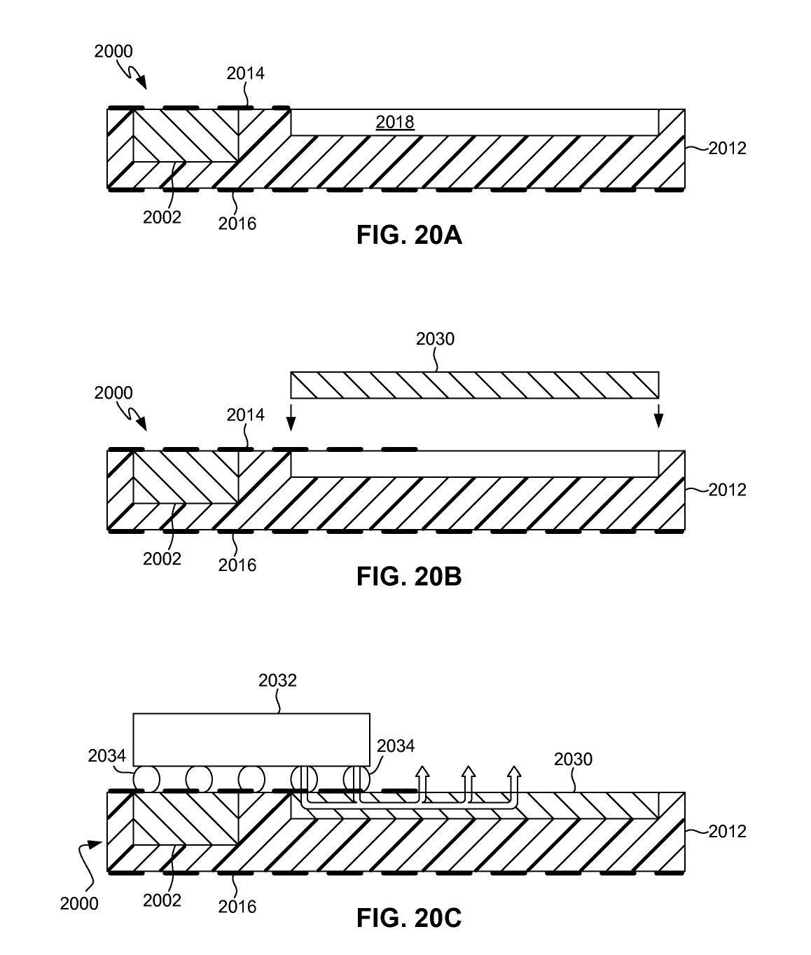

As illustrated in FIG. 20A, a semiconductor device package 2000 is similar to semiconductor device package 400 (FIGS. 4A-D) and thus can be formed in the manner described above with regard to FIGS. 1 and 4A-D. Accordingly, semiconductor dies 2002 and 2004 are similar to semiconductor dies 402 and 404; molding material 2012 is similar to molding material 412; RDLs 2014 and 2016 are similar to RDLs 414 and 416; and void 2018 is similar to void 418.

As illustrated in FIGS. 20A-B, a heat pipe 2030 is mounted in void 2018. Heat pipe 2030 is a solid bar-shaped structure made of a thermally conductive material, such as metal, and having a shape that is complementary to the shape of void 2018. (The term “pipe” as used herein is a reference to the function of conveying heat by conduction and is not intended to describe shape.) As illustrated in FIG. 20C, an active electronic device 2032, such as an integrated circuit chip, is mounted on the first surface of semiconductor device package 2000 such that a thermally conductive path is provided between active electronic device 2032 and heat pipe 2030. For example, in the illustrated embodiment some of the solder balls 2034 on active electronic device 2032 can electrically couple active electronic device 2032 to signal paths (not shown) of RDL 2014, while others of solder balls 2034 can thermally couple active electronic device 2032 to heat pipe 2030. The path through which heat is conducted away from active electronic device 2032 through heat pipe 2030 and ultimately dissipated from the surface of heat pipe 2030 is indicated by arrows in FIG. 20C.

One or more illustrative embodiments of the invention have been described above. However, it is to be understood that the invention is defined by the appended claims and is not limited to the specific embodiments described.

1. A method for forming a semiconductor device package, comprising:
mounting at least one semiconductor die on an adhesive tape substrate;
mounting at least one sacrificial structure made of a sacrificial material on the adhesive tape substrate;
applying molding material on the adhesive tape substrate to embed at least a portion of the at least one semiconductor die and at least a portion of the at least one sacrificial structure;
removing the adhesive tape substrate to define a package assembly having at least a portion of the at least one semiconductor die and at least a portion of the at least one sacrificial structure on a first surface of the package assembly;
forming at least one metal redistribution layer having a plurality of conductive circuit paths on the first surface of the package assembly, at least a portion of the conductive circuit paths in electrical contact with one or more signal pads of the semiconductor die; and
removing at least a portion of the sacrificial material embedded in the molding material to form at least one void in the molding material having a shape corresponding to a shape of the portion of the sacrificial material embedded in the molding material.

2. The method of claim 1, wherein the step of removing at least a portion of the sacrificial material embedded in the molding material comprises one of dissolving, etching and thermally decomposing the portion of the sacrificial material embedded in the molding material.

3. The method of claim 1, wherein:
the step of mounting at least one sacrificial structure comprises mounting a first sacrificial structure having a length extending in a direction substantially normal to the adhesive tape substrate;
the step of applying molding material comprises applying a layer of molding material having a thickness greater than the length of the first sacrificial structure and extending between the first surface of the package assembly and a second surface of the package assembly; and
the at least one void includes a first void having an opening on the first surface and a bottom between the first surface and the second surface.

4. The method of claim 3, wherein an area of the bottom of the first void is greater than an area of the opening of the first void.

5. The method of claim 1, wherein:
the step of mounting at least one sacrificial structure comprises mounting a first sacrificial structure having a length extending in a direction substantially normal to the adhesive tape substrate;
the step of applying molding material comprises applying a layer of molding material having a thickness less than the length of the first sacrificial structure and extending between the first surface of the package assembly and a second surface of the package assembly; and
the at least one void includes a first void defining a first aperture extending completely through the layer of molding material between the first surface and the second surface.

6. The method of claim 5, further comprising mounting an opto-electronic communication device on one of the first and second surfaces of the package assembly, the opto-electronic communication device having an optical axis aligned with the first aperture, the opto-electronic communication device making a plurality of electrical signal connections with one of the first and second metal redistribution layers.

7. The method of claim 6, further comprising inserting an end of an optical fiber into the first aperture.

8. The method of claim 6, wherein:
the step of mounting at least one sacrificial structure comprises mounting a second sacrificial structure having a length extending in a direction substantially normal to the adhesive tape substrate; and
the at least one void further includes a second void having a shape corresponding to a shape of the portion of the sacrificial material of the second sacrificial structure embedded in the molding material.

9. The method of claim 8, further comprising providing a connector assembly having an end of an optical fiber cable retained therein, the connector assembly having a pin mechanically mateable with the second void, the connector assembly having an optical axis alignable with the first aperture by mating the pin with the second void.

10. The method of claim 1, wherein the step of mounting at least one semiconductor die on an adhesive tape substrate comprises mounting an opto-electronic communication device on the adhesive tape.

11. The method of claim 10, wherein the opto-electronic communication device includes an opto-electronic transmitter device and an opto-electronic receiver device.

12. The method of claim 10, further comprising providing a connector assembly having an end of an optical fiber cable retained therein, the connector assembly having a pin mechanically mateable with the at least one void, the connector assembly having an optical axis alignable with an optical axis of the opto-electronic communication device by mating the pin with the at least one void.

13. The method of claim 10, further comprising providing a lens device, the lens device having a pin mechanically mateable with the at least one void, the lens device having an optical axis alignable with an optical axis of the opto-electronic communication device by mating the pin with the at least one void.

14. The method of claim 10, further comprising providing a reflector device, the reflector device having a pin mechanically mateable with the at least one void, the reflector device having an optical axis alignable with an optical axis of the opto-electronic communication device by mating the pin with the at least one void.

15. The method of claim 1, further comprising inserting a fastening member having a shape substantially complementary to the shape of the at least one void into the at least one void to mechanically engage the fastening member with the package assembly.

16. The method of claim 15, wherein:
the at least one void includes a first void having an opening on the first surface and a bottom between the first surface and the second surface; and
inserting a fastening member comprises snap-engaging the fastening member with the first void.

17. The method of claim 1, wherein the at least one void defines a cavity having an opening on the first surface and having a bottom between the first surface and the second surface, the method further comprising:
mounting an opto-electronic transceiver device on the first surface, the optical transceiver device straddling the first surface and the void, the opto-electronic transceiver device making a plurality of electrical signal connections with the first metal redistribution layer, the opto-electronic transceiver device having optical transmit and receive axes aligned with a region of the cavity.

18. The method of claim 1, wherein the at least one void defines a cavity having an opening on the first surface and a bottom between the first surface and the second surface, the method further comprising:
mounting a cover on the first surface, the cover straddling the first surface and the cavity; and
filling the cavity with a liquid adhesive.

19. The method of claim 1, wherein the at least one void defines a channel having an opening on the first surface, a bottom between the first surface and the second surface, and at least one reflector surface oriented at an oblique angle with respect to the first surface, the method further comprising:
applying an optically reflective material to the at least one reflector surface to form a reflective surface; and
mounting an opto-electronic device on the first surface, the opto-electronic device making a plurality of electrical signal connections with the first metal redistribution layer, the opto-electronic device having an optical axis aligned with the reflective surface.

20. The method of claim 1, wherein the at least one void defines a cavity having an opening on the first surface and a bottom between the first surface and the second surface, the method further comprising:
mounting a thermally conductive member in the cavity; and
mounting an active electronic device on the first surface, the active electronic device straddling the first surface and the cavity, the active electronic device making a plurality of electrical signal connections with the first metal redistribution layer, the active electronic device making a thermally conductive connection with the thermally conductive member.
